(19) United States
(12) Patent Application Publication
(10) Pub. No.: US 2014/0326294 A1
(43) Pub. Date: Nov. 6, 2014

(54) SOLAR POWER GENERATION PANEL UNIT AND SOLAR POWER GENERATION APPARATUS

(71) Applicant: Panasonic Corporation, Osaka (JP)

(72) Inventor: Kazuo Inoue, Osaka (JP)

(21) Appl. No.: 14/368,319

(22) PCT Filed: Jun. 10, 2013
(86) PCT No.: PCT/JP2013/003626

§ 371 Date: Jun. 24, 2014

(30) Foreign Application Priority Data
Oct. 25, 2012 (JP) 2012-235769

(51) Int. Cl. H01L 31/052; H01L 31/042

(52) U.S. Cl. CPC H01L 31/0522; H01L 31/0422
USPC 136/246; 136/251

(57) ABSTRACT

A second panel and a third panel are arranged on both sides of a first panel in a width direction, the panels have an identical length and are parallel to each other so that a difference in level is provided between the first panel and the second panel or the third panel with a gap, a width of the first panel is three times or more a width of the second panel and is three times or more a width of the third panel, and when a width of an entire panel unit as a total of the widths of the first to third panels is 1, a ratio of the difference in level between the front surface of the first panel and the front surface of the second panel is 0.05 to 0.1.

### TECHNICAL FIELD

The present invention relates to a solar power generation panel unit and a solar power generation apparatus reducing an influence of wind, in a power generation panel unit and a power generation apparatus on which a module converting solar energy to electric energy is mounted.

### BACKGROUND ART

A solar power generation panel unit has a maximum power generation efficiency when the sun directs in a normal direction of a panel. When the panel is fixed, a direction of the panel cannot be changed. However, even when the direction of the panel is variable, the direction cannot be changed in a state where the sun shines to enable power generation unless wind blows above a wind speed at which a retracting operation is performed for safety of the apparatus.

Therefore, to improve the safety of the apparatus, it is necessary to reduce a wind load received on the panel.

A force received on the panel is maximum when wind blows from a direction perpendicular to a surface of the panel. In this case, when F is a wind load received on the panel, ρ is a density of air, V is a wind speed, S is an area of the panel, and C is a resistance coefficient, Equation 1 is as follows:

F=1/2ρV²SC (Equation 1)

Energy per unit area irradiated with sunlight is determined. Therefore, when a power generation efficiency of the power generation panel becomes higher, area S of the panel necessary for obtaining the same power generation amount can be reduced. A typical power generation panel which is made of a silicon material has a theoretical power generation efficiency of 27%, whereas a concentrating power generation panel has a power generation efficiency of 40% or more at present. The concentrating power generation panel can thus be reduced in size to lower a wind load received thereon.

When the area of the panel is determined, to reduce wind load F received on the panel with respect to constant wind speed V, resistance coefficient C in Equation 1 is required to be lowered. Resistance coefficient C depends on panel shape.

In Patent Literature 1, a plurality of strip-shaped panels are provided with a gap between the adjacent panels. In Patent Literature 1, each of the strip-shaped panels has a rotational shaft in a longitudinal direction to change its direction. A wind load received on each panel is reduced to lower a load received on its rotation driving section.

In Patent Literature 2, a plurality of strip-shaped panels in two rows are spaced from each other in a thickness direction so that the adjacent panels are staggered. In the drawing in Patent Literature 2, each of the panels has a constant width and interval between the panels, and is formed on its side surface with a cooling fin. In addition, the panels are integrated to have one rotational shaft for changing their direction. In a concentrating solar power generation, a power generation module is irradiated in its entirety with light, frames in two rows being overlapped with each other. An area on a side onto which the light is incident is thus minimized.

In Patent Literature 3, there is no wind load description, and regular square panels are arranged in three dimensions so that the adjacent panels are staggered in a thickness direction. As in Patent Literature 2, in Patent Literature 3, in a concentrating solar power generation, a power generation module is irradiated in its entirety with light, frames of the adjacent power generation modules being overlapped with each other. An area of each of the panels is thus minimized.

### CITATION LIST

### Patent Literature

Patent Literature 1: Japanese Patent Publication (JP-B) No. 4-76233

Patent Literature 2: USP2010-0126554

Patent Literature 3: USP2011-0056540

### SUMMARY OF INVENTION

### Technical Problem

However, in Patent Literature 1, the adjacent panels are provided with the gap, seen from the sun side. A floor area occupied by the panels thus becomes larger. In addition, each of the panels has the rotation driving section. The apparatus which is complicated in mechanism thus becomes larger.

In Patent Literature 2, the width of each of the panels is narrow, the adjacent panels being staggered. A large number of members connecting the panels are necessary. A periphery of each of the power generation panels becomes heavier. A driving device and a supporting post are thus required to be larger.

Likewise, in Patent Literature 3, a large number of members connecting the panels are necessary. A periphery of each of the power generation panels becomes heavier. A driving device or a supporting post are thus required to be larger.

An object of the present invention is to provide a solar power generation panel unit and a solar power generation apparatus capable of reducing a wind load received on a power generation panel.

### Solution to Problem

To solve the conventional problems, a solar power generation panel unit according to an aspect of the present invention, comprises:

a first panel;

a second panel that is arranged on one side of the first panel in a width direction; and

a third panel that is arranged on an other side opposite to the one side of the first panel in the width direction,

wherein the first panel, the second panel, and the third panel have an identical length and are parallel to each other so that a difference in level is provided between the first panel and the second panel with a gap in a direction perpendicular to front surfaces of the first and second panels and that a difference in level is provided between the first panel and the third panel with a gap in a direction perpendicular to front surfaces of the first and third panels,

wherein a width of the first panel is three times or more a width of the second panel and is three times or more a width of the third panel,

wherein when a width of an entire panel unit as a total of the widths of the first panel, the second panel, and the third panel is 1, a ratio of the difference in level between the front surface of the first panel and the front surface of the second panel is 0.05 to 0.1.

### Advantageous Effects of Invention

According to the solar power generation panel unit and the solar power generation apparatus of the aspect of the present invention, a wind load received on the panels can be reduced even when wind blows to the panel unit from either side thereof.

### BRIEF DESCRIPTION OF DRAWINGS

These and other objects and features of the present invention will become apparent from the following description taken in connection with the preferred embodiments thereof with reference to the accompanying drawings. In the drawings, in which:

FIG. 1 is a perspective view showing a solar power generation apparatus of a first embodiment of the present invention;

FIG. 2 is a perspective view showing a power generation module used for a solar power generation panel unit of the first embodiment of the present invention;

FIG. 3 is a side view of the solar power generation apparatus of the first embodiment of the present invention, in which a panel is taken in a longitudinal direction ahead of a supporting post;

FIG. 4 is a plan view of the solar power generation panel unit of the first embodiment of the present invention, seen from above after panels in FIG. 1 are erected in a vertical direction;

FIG. 5 is a block diagram of an operation of directing to the sun the solar power generation panel unit in the solar power generation apparatus of the first embodiment of the present invention;

FIG. 6 is a relation chart comparing relations between wind loads received on the solar power generation panel unit including the first embodiment of the present invention and widths of a center panel 1 according to directions of wind blowing perpendicularly to front surfaces of panels;

FIG. 7A is a relation chart comparing relations between maximum wind loads received on the solar power generation panel unit including the first embodiment of the present invention and widths of the center panel 1 according to differences in level between the center panel 1 and the adjacent panels;

FIG. 7B is a view showing data of wind loads used in FIGS. 7A and 9;

FIG. 7C is a relation chart comparing relations between maximum wind loads received on the solar power generation panel unit with two-axis symmetry and widths of the center panel 1 according to differences in level between the center panel 1 and the adjacent panels;

FIG. 8A is a schematic view showing directions of air flows flowing near the solar power generation panel unit of the first embodiment of the present invention;

FIG. 8B is a schematic view showing directions of air flows flowing near the solar power generation panel unit of the first embodiment of the present invention;

FIG. 8C is a schematic view showing directions of air flows flowing near the solar power generation panel unit of the first embodiment of the present invention;

FIG. 8D is a view explaining a difference in level and a gap in the solar power generation panel unit of the first embodiment of the present invention;

FIG. 9 is a relation chart comparing relations between maximum wind loads received on the solar power generation panel unit including the first embodiment of the present invention and differences in level between the panels according to widths of the center panel 1;

FIG. 10 is a relation chart showing relations between maximum wind loads received on the solar power generation panel unit including the first embodiment of the present invention and thicknesses of the panel;

FIG. 11 is a relation chart of relations between wind loads received on the solar power generation panel unit of the first embodiment of the present invention and wind speeds;

FIG. 12A is a flow line distribution view in which the center panel is located on an upwind side of the adjacent panel at a wind speed of 60 m/s;

FIG. 12B is a flow line distribution view in which the center panel is located on an upwind side of the adjacent panel at a wind speed of 2 m/s;

FIG. 13A is a flow line distribution view in which the center panel is located on a downwind side of the adjacent panel at a wind speed of 60 m/s;

FIG. 13B is a flow line distribution view in which the center panel is located on a downwind side of the adjacent panel at a wind speed of 2 m/s;

FIG. 14A is a schematic sectional view of a solar power generation panel unit of a second embodiment of the present invention, taken in a lateral direction;

FIG. 14B is a schematic sectional view of the solar power generation panel unit of the second embodiment of the present invention, taken in a lateral direction;

FIG. 15A is a schematic sectional view of a solar power generation panel unit of a third embodiment of the present invention, taken in a lateral direction;

FIG. 15B is a schematic sectional view of the solar power generation panel unit of the third embodiment of the present invention, taken in a lateral direction;

FIG. 16 is a schematic sectional view of a conventional solar power generation panel unit, taken in a lateral direction;

FIG. 17 is a front view of the solar power generation panel unit of the first embodiment of the present invention; and

FIG. 18 is a view showing the solar power generation panel unit according to the first embodiment of the present invention, seen from a first panel (a second panel or a third panel) in a longitudinal direction.

### DESCRIPTION OF EMBODIMENTS

Hereinafter, embodiments according to the present invention will be described in detail with reference to the drawings.

Before describing the embodiments according to the present invention, findings which are a basis for the present invention will be described.

To make a wind load received on each power generation panel lower than the conventional art, it is necessary to solve (1) a problem that the wind load received on the panel is reduced to direct the panel in a sunlight receiving direction, and (2) a problem desired to make the wind load reduced even when wind blows to the panel from either the front or back side thereof in perpendicular incidence in which the wind load received on the panel is maximum, since a wind blowing direction is irregular.

In Patent Literature 2, a wind load received on the laterally arranged panels is reduced by providing the gap in the thickness direction between the panels.

Accordingly, a degree of the wind load in Patent Literature 2 was examined by an experiment.

Specifically, a gap between staggered panels 91 each having a short side of 10 cm was 4 cm. As a comparative example to be compared with later-studied working examples of the embodiments of the present invention, an entire panel unit had a regular square shape with a side of 1 m so that nine strip-shaped equal-width panels 91 each having a thickness of 3 cm and a length of 1 m were staggered with a dimension of the gap of 4 cm. Then, when wind blew uniformly at 20 m/s to the panels 91 from a direction perpendicular to front surfaces thereof, a wind load is numerically analyzed. A block diagram of this configuration is shown in FIG. 16. The arrow in FIG. 16 represents a direction of the wind. The panels 91 each had a thickness of 3 cm for equaling to panels for the working examples studied by the present inventors. The wind speed of 20 m/s was an upper limit to perform a power generating operation. In excess of the wind speed, a retracting posture for safety was taken. The present inventors made the panel unit having a symmetric shape with respect to the wind so as to apply no rotation moment onto a supporting post supporting the panels 91.

As analysis software, SCRYU TETRA manufactured by Software Cradle Co., Ltd. was used to perform steady analysis in SSTk-co model.

As an experiment result, the wind load received on the panels was 277 N.

On the other hand, flat plate panels each having a side of 1 m and a thickness of 3 cm were used. Likewise, wind blew uniformly at 20 m/s to the panels from a direction perpendicular to surfaces thereof. In this case, a wind load received on the panels was 307 N.

From this, the wind load of the configuration in Patent Literature 2 was reduced by only 10% of the wind load of the flat plates.

Accordingly, the present inventors have eagerly studied to make the present invention by finding that a particular arranging configuration among a width of each panel, a width of an entire panel unit and a difference in level between panels can reduce a wind load greatly than the conventional art.

Before describing the embodiments according to the present invention with reference to the drawings in details, various aspects of the present invention are explained.

According to a first aspect of the present invention, there is provided a solar power generation panel unit comprising:

a first panel;

a second panel that is arranged on one side of the first panel in a width direction; and

a third panel that is arranged on an other side opposite to the one side of the first panel in the width direction,

wherein the first panel, the second panel, and the third panel have an identical length and are parallel to each other so that a difference in level is provided between the first panel and the second panel with a gap in a direction perpendicular to front surfaces of the first and second panels and that a difference in level is provided between the first panel and the third panel with a gap in a direction perpendicular to front surfaces of the first and third panels,

wherein a width of the first panel is three times or more a width of the second panel and is three times or more a width of the third panel,

wherein when a width of an entire panel unit as a total of the widths of the first panel, the second panel, and the third panel is 1, a ratio of the difference in level between the front surface of the first panel and the front surface of the second panel is 0.05 to 0.1.

According to the aspect, a wind load received on the panels can be reduced even when wind blows to the panel unit from either side thereof.

According to a second aspect of the present invention, there is provided the solar power generation panel unit according to the first aspect, wherein when the width of the entire panel unit is 1, a ratio of a dimension of the gap obtained by subtracting a thickness of the first panel from the difference in level between the front surface of the first panel and the front surface of the second panel is 0.02 to 0.07.

According to the aspect, the ratio of the dimension of the gap to the width of the entire panel unit is 0.02 to 0.07. Therefore, a wind load received on the panels can be reduced more reliably.

According to a third aspect of the present invention, there is provided the solar power generation panel unit according to the first or second aspect, wherein when the width of the entire panel unit is 1, a ratio of a thickness of each of the panels is 0.01 to 0.05.

According to the aspect, the ratio of the thickness of each of the panels to the width of the entire panel unit is 0.01 to 0.05. Therefore, a wind load received on the panels can be reduced more reliably.

According to a fourth aspect of the present invention, there is provided the solar power generation panel unit according to any one of the first to third aspects, wherein the second panel and the third panel are symmetric with respect to a plane perpendicular to the front surface of the first panel and passing through a center axis in the width direction.

According to the aspect, the panel unit is supported by a supporting post perpendicular to the front surface of the first panel and along the center axis in the width direction. Therefore, rotation moment about the center axis can be prevented, thereby reducing a wind load received on the panels more reliably.

According to a fifth aspect of the present invention, there is provided the solar power generation panel unit according to any one of the first to fourth aspects, wherein the panels are supported in a width direction or a thickness direction of the panels.

According to the aspect, between the first panel and the second panel and between the first panel and the third panel, air flows flowing in the width direction of the panels cannot be inhibited. Therefore, a wind load can be reduced.

According to a sixth aspect of the present invention, there is provided the solar power generation panel unit according to any one of the first to fifth aspects, wherein each of the panels has a plurality of concentrating solar power generation elements.

According to the aspect, the power generation panel unit can be of a concentrating type. Therefore, the concentrating power generation panel unit can be smaller than a non-concentrating power generation panel unit.

According to a seventh aspect of the present invention, there is provided the solar power generation panel unit according to the sixth aspect, wherein a light concentrating member that covers each of the concentrating solar power generation elements is not overlapped with adjacent panels in the direction perpendicular to the front surfaces of the panels.

According to the aspect, while a solar power generation efficiency can be avoided from being lowered, a wind load received on the panels can be reduced.

According to an eighth aspect of the present invention, there is provided the solar power generation panel unit according to the sixth or seventh aspect, wherein an air layer is not provided between the concentrating solar power generation element and the light concentrating member.

According to the aspect, since even the small solar power generation panel can be thinner, the difference in level having the gap between the panels can be smaller. Therefore, a wind load received on the panels can be reduced.

According to a ninth aspect of the present invention, there is provided a solar power generation panel unit comprising:

a first panel;

a second panel that is arranged on one side of the first panel in a width direction; and

a third panel that is arranged on an other side opposite to the one side of the first panel in the width direction,

wherein the first panel is arranged on an upwind side of the second panel and the third panel,

wherein the first panel, the second panel, and the third panel have an identical length and are parallel to each other so that a difference in level is provided between the first panel and the second panel with a gap in a direction perpendicular to front surfaces of the first and second panels and that a difference in level is provided between the first panel and the third panel with a gap in a direction perpendicular to front surfaces of the first and third panels,

wherein a width of the first panel is three times or more a width of the second panel and is three times or more a width of the third panel,

wherein wind incident onto the front surface of the first panel forms air streams directing to both sides along the front surface of the first panel, and the air streams directing to both sides along the front surface of the first panel collide with wind directing to the second panel and the third panel before reaching the second panel and the third panel to blow away the wind directing to the second panel and the third panel to outside of the second panel and the third panel.

According to the aspect, the air streams directing to both sides along the front surface of the first panel collide with the wind directing to the second panel and the third panel to blow away the wind to outside of the second panel and the third panel. Positive pressures received on the front surfaces (upwind surfaces) of the second panel and the third panel thus become lower. Therefore, a wind load received on the entire panel unit can be reduced.

According to a tenth aspect of the present invention, there is provided a solar power generation panel unit comprising:

a first panel;

a second panel that is arranged on one side of the first panel in a width direction; and

a third panel that is arranged on an other side opposite to the one side of the first panel in the width direction,

wherein the first panel is arranged on a downwind side of the second panel and the third panel,

wherein the first panel, the second panel, and the third panel have an identical length and are parallel to each other so that a difference in level is provided between the first panel and the second panel with a gap in a direction perpendicular to front surfaces of the first and second panels and that a difference in level is provided between the first panel and the third panel with a gap in a direction perpendicular to front surfaces of the first and third panels,

wherein a width of the first panel is three times or more a width of the second panel and is three times or more a width of the third panel,

wherein wind incident onto the front surface of the first panel forms air streams directing to both sides along the front surface of the first panel, and the air streams enter into the gap between the first panel and the second panel and the gap between the first panel and the third panel to flow along a back surface of the second panel and a back surface of the third panel.

According to the aspect, the air streams directing to both sides along the front surface of the first panel enter into the gaps to flow along the back surfaces of the second panel and the third panel. Absolute values of negative pressures received on the back surfaces (downwind surfaces) of the second panel and the third panel thus become lower. Therefore, a wind load received on the entire panel unit can be reduced.

According to an 11th aspect of the present invention, there is provided a solar power generation panel unit comprising:

a first panel;

a second panel that is arranged on one side of the first panel in a width direction; and

a third panel that is arranged on an other side opposite to the one side of the first panel in the width direction,

wherein the first panel is arranged on an upwind side of the second panel and the third panel,

wherein the first panel, the second panel, and the third panel have an identical length and are parallel to each other so that a difference in level is provided between the first panel and the second panel with a gap in a direction perpendicular to front surfaces of the first and second panels and that a difference in level is provided between the first panel and the third panel with a gap in a direction perpendicular to front surfaces of the first and third panels,

wherein a width of the first panel is three times or more a width of the second panel and is three times or more a width of the third panel,

wherein wind incident onto the front surface of the first panel forms air streams directing to both sides along the front surface of the first panel, and the air streams enter into the gap between the first panel and the second panel and the gap between the first panel and the third panel to flow along a back surface of the first panel.

According to the aspect, the air streams directing to both sides along the front surface of the first panel enter into the gaps to flow along the back surface of the first panel. An absolute value of negative pressure received on the back surface (downwind surface) of the first panel thus becomes lower. Therefore, a wind load received on the entire panel unit can be reduced.

According to a 12th aspect of the present invention, there is provided a solar power generation apparatus comprising:

the solar power generation panel unit according to any one of the first to 11th aspects;

a posture driving section that independently moves the solar power generation panel unit in an elevation angle direction and in an azimuth direction;

a supporting post that supports all the panels; and

a controller that controls the posture driving section to allow a direction of the solar power generation panel unit to track sun based on information from the posture driving section.

According to the aspect, a wind load received on the panels can be reduced even when wind blows to the panel unit from either side thereof. In addition, the number of panels is small, the panels are thin, and a difference in level between the panels is small. The number of members connecting the panels is small to reduce the weight of the panels including peripheries thereof. Therefore, any load and moment onto the supporting post supporting the panels can be reduced to improve safety. In addition, energy moving the panels can be reduced.

According to a 13th aspect of the present invention, there is provided the solar power generation apparatus according to the 12th aspect, wherein a longitudinal direction of each of the first panel, the second panel, and the third panel is arranged along a longitudinal direction of the supporting post.

According to the aspect, the first panel is most close to the supporting post, not only when the first panel is located on the supporting post side from the second panel and the third panel, but also when the second panel and the third panel are located on the supporting post side from the first panel. Although the solar power generation apparatus has the second panel and the third panel, the second panel and the third panel are unlikely to come into contact with the supporting post. A distance between a rotation center of a joint supporting the panel unit and the panel unit and a distance between the first panel and the supporting post can be shortened to the same length as the solar power generation apparatus having only the first panel and the supporting post. As a result, an abrupt increase in rotation moment applied onto the supporting post can be reduced.

According to a 14th aspect of the present invention, there is provided the solar power generation apparatus according to the 12th aspect, wherein when a border line between the first panel and the second panel or the third panel in a plane seen from the front surfaces of the first panel, the second panel, and the third panel crosses the longitudinal direction of the supporting post, the first panel is closer to the supporting post than the second panel and the third panel.

According to the aspect, the first panel is most close to the supporting post. Therefore, a possibility that the second panel and the third panel come into contact with the supporting post can be reduced. In addition, a distance between the first panel and the supporting post can be shortened to the same length as the solar power generation apparatus having only the first panel and the supporting post. Therefore, an abrupt increase in rotation moment applied onto the supporting post can be reduced.

Hereinafter, the embodiments of the present invention will be described with reference to the drawings.

### First Embodiment

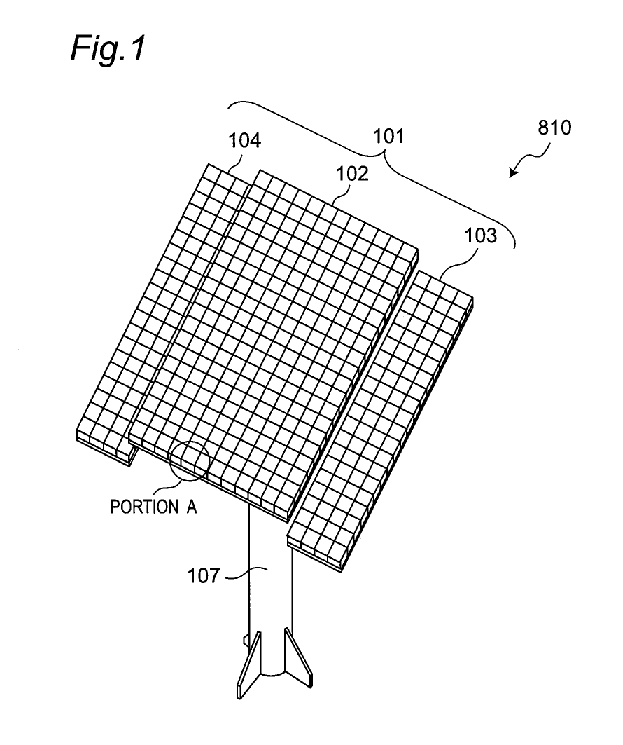

FIG. 1 is a perspective view of a solar power generation apparatus 810 mounting thereon a solar power generation panel unit 101 according to a first embodiment of the present invention.

In FIG. 1, reference numeral 101 is the power generation panel unit. The power generation panel unit 101 has a first panel 102 arranged at a center thereof and having a quadrilateral (as an example, rectangular) plate shape, a second panel 103 having a quadrilateral (as an example, rectangular) plate shape, and a third panel 104 having a quadrilateral (as an example, rectangular) plate shape. The second panel 103 and the third panel 104 are adjacent to both outer sides of the first panel 102 in a width direction.

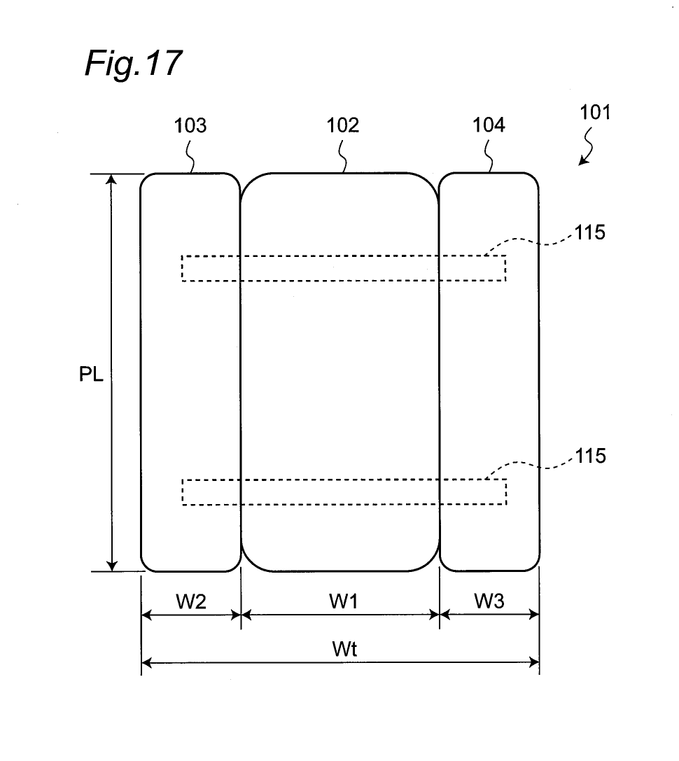

The first panel 102, the second panel 103, and the third panel 104 have the same length PL (see FIG. 17), and are parallel to each other.

A difference in level is provided between the first panel 102 and the second panel 103 with gap G1 in a direction perpendicular to front surfaces of thereof. A difference in level is provided between the first panel 102 and the third panel 104 with crap G2 in a direction perpendicular to front surfaces thereof. That is, the first panel 102, the second panel 103, and the third panel 104 are supported by a supporting post 107 so that the second panel 103 and the third panel 104 are shifted from the first panel 102 downward by the differences in one level. To avoid a solar power generation efficiency from being lowered, the second panel 103 and the third panel 104 are not overlapped with the first panel 102. More specifically, as an example, beams 115 are located in upper and lower portions in FIG. 1, extend in the width direction (along short sides) of the first panel 102, connect and support the first panel 102 and the second panel 103, and connect and support the first panel 102 and the third panel 104. As described later, the first panel 102 is rotatably supported at a back surface thereof by the supporting post 107.

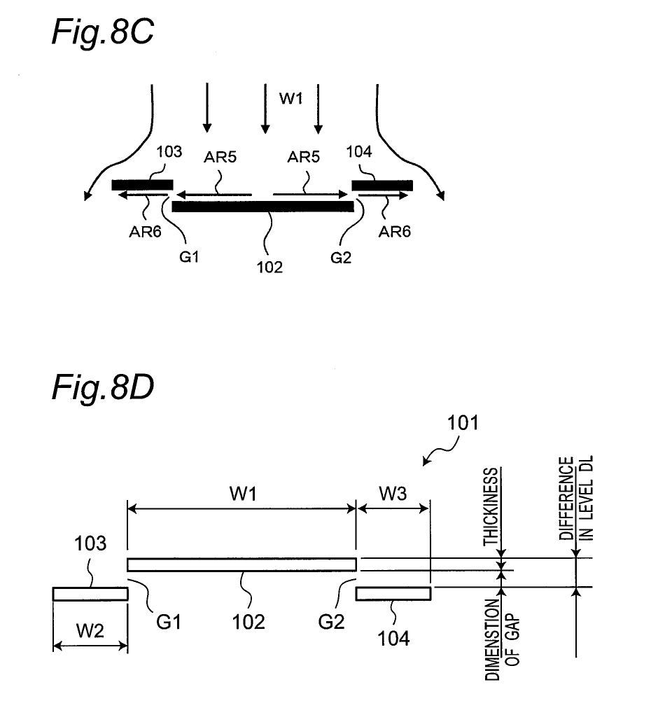

In addition, as described later, in detail, the width W1 of the first panel 102 is three times or more the width W2 of the second panel 103 and is three times or more the width W3 of the third panel 104. Further, when the width Wt of the entire panel unit which is a total of the width W1 of the first panel 102, the width W2 of the second panel 103, and the width W3 of the third panel 104 is 1, a ratio of difference in level DL between the front surface of the first panel 102 and the front surface of the second panel 103 is 0.05 to 0.1 (see FIG. 17) As shown in FIG. 8D, difference in level DL means a dimension between the front surface of the first panel 102 and the front surface of the second panel 103 or the third panel 104.

The three panels 102, 103, and 104 at two stages are symmetric with respect to a center axis in a longitudinal direction and a center axis in the width direction of the first panel 102. A wind load acts to be symmetric with respect to the first panel 102 at the center axes in an up-down direction and in a left-right direction.

The panels have the same thickness T.

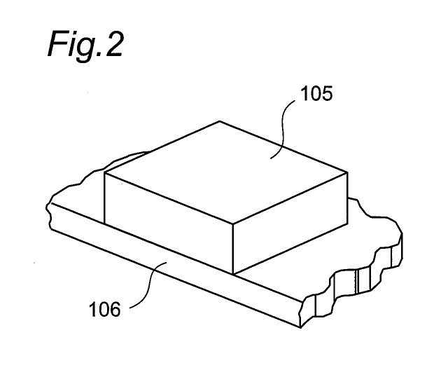

FIG. 2 shows an enlarged view of port ion A as a portion of the first panel 102. FIG. 2 shows a power generation module 105, and a substrate 106 supporting the power generation module 105. To be easily seen, only one power generation module 105 is shown. Each of the first panel 102, the second panel 103, and the third panel 104 of the power generation panel unit 101 has a large number of power generation panel units 101 arranged on the substrate 106.

Each of the first panel 102, the second panel 103, and the third panel 104 is constituted by the power generation modules 105, and the substrate 106 which is a base of the power generation modules 105. Each of the concentrating power generation modules 105 has, as an example, a regular square shape with a side of 5 cm and a thickness of 2 cm. The power generation module 105 is constituted by light concentrating member, a power generation element converting light energy concentrated by the light concentrating member to electric energy, and an electric wire connected to the power generation element. The light concentrating member used for the power generation module 105 may include collected convex lenses or a Fresnel lens. Therefore, since the second panel 103 and the third panel 104 are not overlapped with the first panel 102, as an example, the light concentrating member which covers the power generation module 105 as the concentrating solar power generation element is not overlapped with each of the adjacent panels in a direction perpendicular to front surfaces of the panels.

In order that the thickness of the power generation module 105 can be 2 cm, the thickness of the light concentrating member becomes smaller. In this case, since a focal length is required to be within the thickness of the power generation module 105, as an example, the light concentrating member and the power generation element are directly joined. The reason of such a configuration is as follows. That is, since air has a refraction factor of 1, as compared with when the power generation module 105 has only the optical member, when the power generation module 105 has an air layer sandwiched between the light concentrating member and the power generation element, not only an actual optical path length, but also the number of interfaces, is increased. Due to this, interface reflection reduces the amount of light incident onto the power generation element. To improve an assembling precision and rigidity of the power generation module, as an example, the light concentrating member and the power generation element are directly joined.

As an example, the substrate 106 is made of aluminum, releases heat from the power generation module 105, and has a thickness of 1 cm. Therefore, as an example, from the thicknesses of the power generation module 105 and the substrate 106, the panels 102, 103, and 104 each have a thickness of 3 cm.

The power generation element which cannot convert all light energy from the sun to electric energy generates heat to increase its temperature. Consequently, the power generation module 105 is required to be smaller than when the power generation module 105 does not concentrate light by the light concentrating member. Such a configuration can increase a free degree of the shape of the panels 102, 103, and 104.

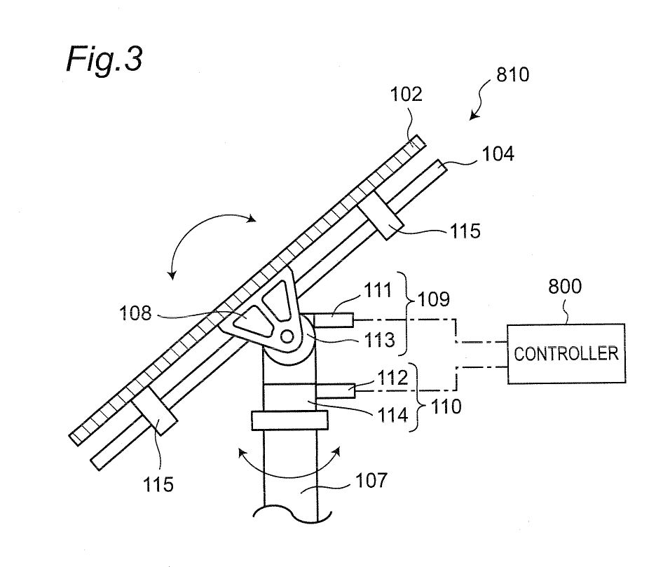

FIG. 3 shows a side view of the power generation panel unit 101 seen from a front of the supporting post 107 after the panel unit 101 is taken in a longitudinal direction ahead of the supporting post 107 seen from a lateral direction. A joint 108 is made of a triangular plate material, and has a bottom surface fixed onto a back surface of the first panel 102 and an apex which is rotatably connected to the supporting post 107. An elevation angle driving device 109 is provided below the joint 108. An azimuth driving device 110 is provided below the elevation angle driving device 109, and is connected to the supporting post 107. The elevation angle driving device 109 and the azimuth driving device 110 configure an example of a posture driving section.

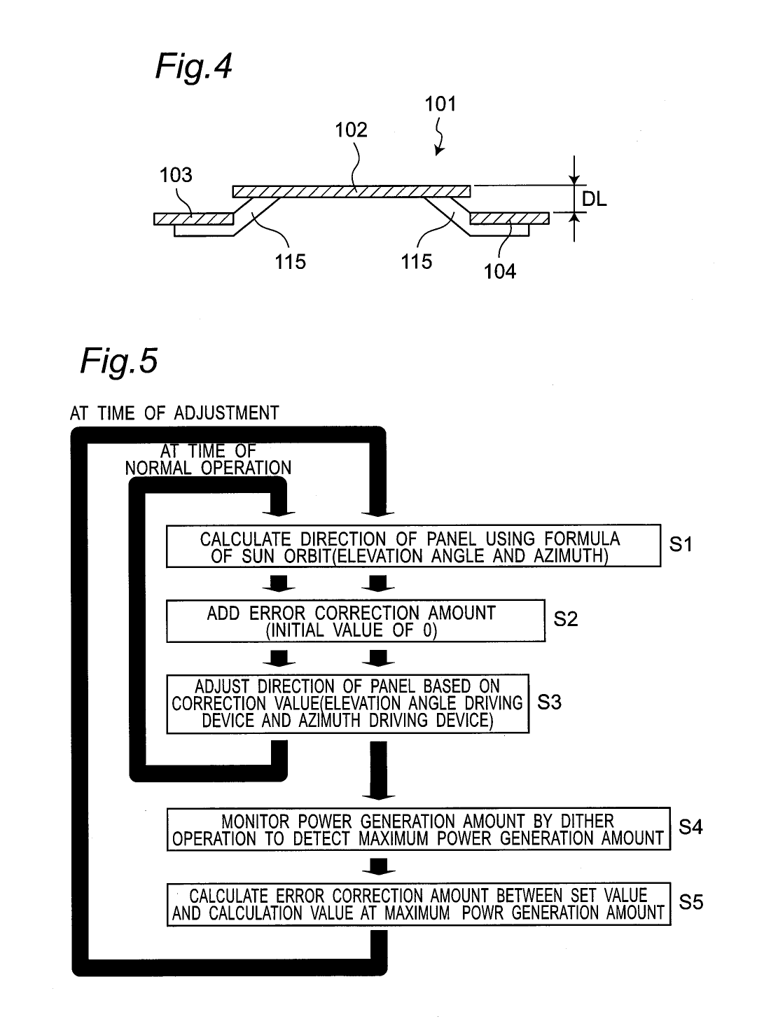

In order that an arrangement of the power generation panel unit 101 and the beams 115 can be easily understood, FIG. 4 shows a plan view showing only the power generation panel unit 101 and the beams 115, seen from above, after the power generation panel unit 101 in FIG. 1 is erected so that front surfaces of the panels are in a vertical direction. The beams 115 are constituted by bar-like members bent in their intermediate portions, and support the first panel 102, the second panel 103, and the third panel 104 forming the power generation panel unit 101 from back surfaces thereof (from a down direction in FIG. 4). In such a configuration supported by the beams 115, the front surfaces of the first panel 102, the second panel 103, and the third panel 104 are parallel to each other.

The elevation angle driving device 109 has a motor 111, and a speed reduction mechanism 113 connected to the motor 111 and having gears. The motor 111 is controlled by a controller 800 to be rotated forward and rearward. The speed reduction mechanism 113 connects the joint 108 and the motor 111. The motor 111 is drivably controlled by the controller 800 to incline the power generation panel unit 101 upward with respect to a horizontal direction by a predetermined angle via the speed reduction mechanism 113 and the joint 108.

The azimuth driving device 110 is constituted by a motor 112, and a speed reduction mechanism 114 connected to the motor 112 and having gears. The motor 112 is controlled by the controller 800 to be rotated forward and rearward. The speed reduction mechanism 114 is arranged between the elevation angle driving device 109 and the supporting post 107. By the motor 112 drivably controlled from the controller 800, the elevation angle driving device 109 can be rotated forward and rearward with respect to the supporting post 107 about an axis of the supporting post 107 by a predetermined angle via the speed reduction mechanism 114. In this way, by controlling the motors 111 and 112 including an elevation angle direction and a rotating direction, an elevation angle and an azimuth of the power generation panel unit 101 are adjusted so that the sun is in a normal direction with respect to a front surface of the power generation panel unit 101. Therefore, the first panel 102, the second panel 103, and the third panel 104 forming the power generation panel unit 101 are required to be parallel to each other.

FIG. 5 shows a flowchart of a method of directing the power generation panel unit 101 to the sun.

In installation of the solar power generation apparatus, there are initially an error in installation shifted from a target direction and an error in the apparatus deformed by its own weight. In addition, when time elapses, the power generation panel unit 101 itself causes an error due to change with time. Therefore, the following procedure is performed at the time of adjustment.

A position of the sun is calculated by using a formula from a date, time, a latitude, and a longitude. An elevation angle and an azimuth are calculated from the formula (see step S1)

Then, an error correction amount is added to each of the elevation angle and the azimuth calculated in step S1. The error correction amount has an initial value of 0.

Then, based on the results of the elevation angle and the azimuth calculated in step S2, the controller 800 drivably independently controls the elevation angle driving device 109 and the azimuth driving device 110 to direct a front surface of the power generation panel unit 101 to the sun (see step S3).

Then, the controller 800 drivably controls the elevation angle driving device 109 and the azimuth driving device 110 to perform a dither operation of moving the power generation panel unit 101 about the position little by little in an elevation angle direction and in an azimuth direction, thereby monitoring a power generation amount by a power generation amount monitor device (not shown) (see step S4)

Then, an error amount between a position in which the power generation amount is maximum and each of the calculated elevation angle and azimuth is calculated to be stored as an error correction amount (see step S5). Here, the calculated elevation angle and azimuth at time in which the power generation amount is maximum are used. The reason is that an error due to a difference in time is added in a case where it takes time for the dither operation.

At the time of a normal operation thereafter, a value obtained by adding the error correction amount to each of the elevation angle and the azimuth calculated from the formula of the sun orbit is each of a corrected elevation angle and a corrected azimuth. Then, the controller 800 independently drives the elevation angle driving device 109 and the azimuth driving device 110 to direct the front surface of the power generation panel unit 101 to the sun (see repeated steps S1 to S3)

Here, the dither operation is performed to calculate the direction of the sun from the power generation amount of the panels, thereby calculating the error correction amount of each of the elevation angle and the azimuth. However, a device detecting the direction of sunlight may be used to calculate the error correction amount of each of the elevation angle and the azimuth.

Of course, when the direction of the sun is examined, it is necessary that the sun shine and the power generation panel unit 101 be not shaded.

As an example, each of the power generation panels 102, 103, and 104 had a strip shape with a length of 1 m and a thickness of 3 cm. Then, the first panel 102 had a width of 0.6 m. The second panel 103 and the third panel 104 each had a width of 0.2 m. A difference in level between the first panel 102 and the second panel 103 or the third panel 104 was 7 cm. A dimension of a gap between the first panel 102 and the second panel 103 or the third panel 104 was 4 cm. A uniform flow at a wind speed of 20 m/s was incident perpendicularly to the front surface of each of the panels to numerically analyze wind loads. The wind speed of 20 m/s was assumed to be a maximum wind speed at the time of the normal operation.

A direction of the power generation panel unit 101 should not be changed according to wind direction during power generation. Therefore, a wind load is required to be lower even when the power generation panel unit 101 is directed in either direction. The wind load calculation was performed when wind blew to the power generation panel unit 101 from both front and back surfaces thereof.

When the first panel 102 was located on an upwind side of the second panel 103 and the third panel 104, a wind load was 249 N. When the wind blew from the opposite direction, a wind load was 242 N.

As a result, when the wind blew to the power generation panel unit 101 from both the front and back surfaces thereof, the wind loads were lower than 277 N in the comparative example.

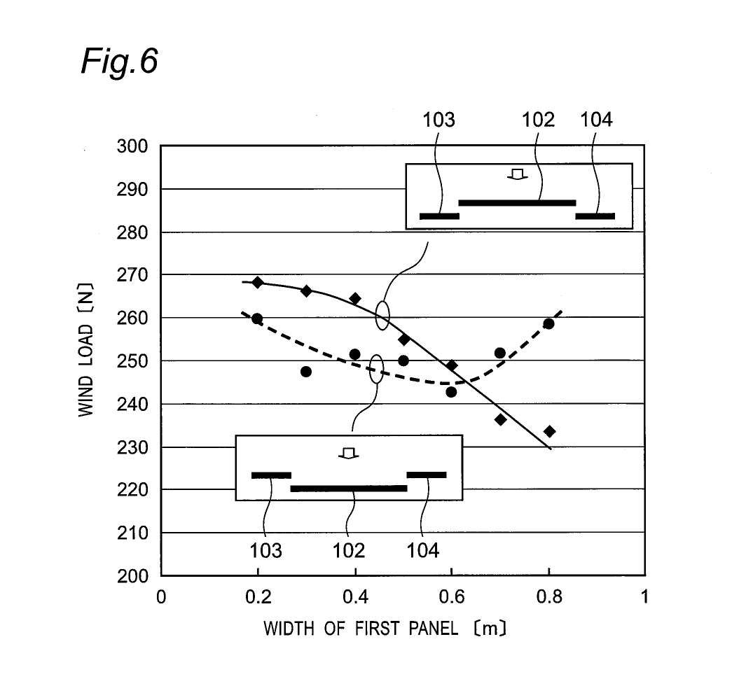

Likewise, the power generation panel unit 101 had three symmetric panels at two stages, which obtained the above good results, to change the first center panel 102 in width every 0.1 m from 0.2 m to 0.8 m. FIG. 6 shows the wind load results. For each diamond mark in FIG. 6, the first center panel 102 was located on an upwind side of the second panel 103 and the third panel 104. For each circular mark in FIG. 6, the first center panel 102 was located on a downwind side of the second panel 103 and the third panel 104. The second panel 103 and the third panel 104 had the same width. The entire power generation panel unit had a width of 1 m. A wind speed was 20 m/s. When the first panel 102 was located on the upwind side of other panels (the second panel 103 or the third panel 104), the wind load was decreased as the width of the first panel 102 was increased. When the first panel 102 was located on the downwind side of other panels, the wind load was minimum when the width of the first panel 102 was 0.6 m. On the other hand, flat plate panels each having a side of 1 m and a thickness of 3 cm were used. Likewise, in a case where wind blew uniformly at 20 m/s to the panels from a direction perpendicular to surfaces thereof, a wind load received on the panels was 307 N.

As a result, the width of the first center panel 102 was within the certain range, so that the wind load became lower even when the wind blew to the power generation panel unit 101 from either side thereof.

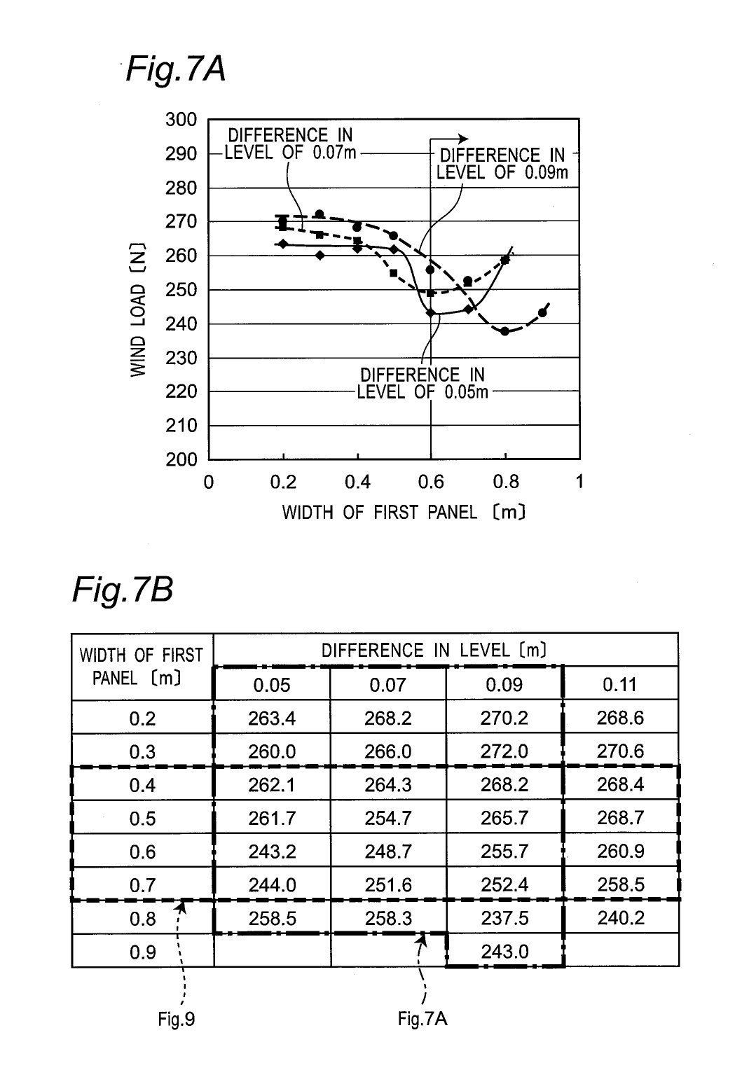

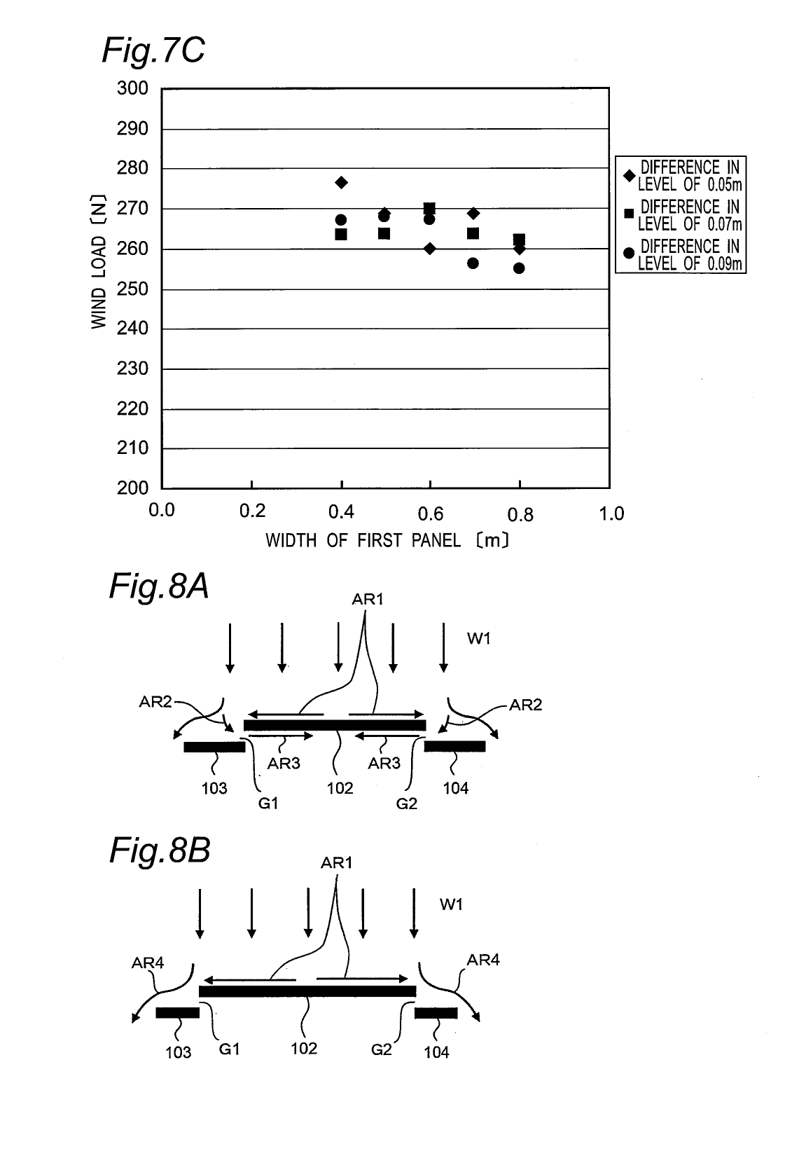

As another example to calculate a wind load, the power generation panels 102, 103, and 104 were three symmetric panels at two stages, each of the panels having a strip shape with a length of 1 m and a thickness of 3 cm. Differences in level were 5 cm, 7 cm, and 9 cm. The first center panel 102 was changed in width every 0.1 m from 0.2 m to 0.8 m. The second panel 103 and the third panel 104 had the same width. The entire power generation panel unit had a width of 1 m. A wind speed was 20 m/s. In FIG. 7A, each diamond mark represents a difference in level of 5 cm, each square mark represents a difference in level of 7 cm, and each circular mark represents a difference in level of 9 cm. In addition, wind loads were calculated when the first center panel 102 was located on upwind and downwind sides of the second panel 103 and the third panel 104. The results are shown in FIGS. 7A and 7B. In FIGS. 7A and 7B, the larger one of the wind loads of wind which blew to the panels from directions perpendicular to front and back surfaces thereof was selected.

From the results in FIGS. 7A and 7B, it is found that when the width of the center panel was 0.6 m or more, the wind load received on the panels became lower even when the wind blew to the panels from either direction thereof.

These studies occurred in the shape in which the panels were symmetric with respect to one axis. The same thing can be considered to apply to the panels symmetric with respect to two axes perpendicular to each other, that is, to a center panel being a regular square plate and square frame plate-shaped panels with a constant width around the center panel.

Accordingly, the present inventors studied a regular square center panel and square frame plate-shaped panels with a constant width around the center panel, which were arranged at two stages and each had a thickness of 3 cm. Differences in level were 5 cm, 7 cm, and 9 cm. The first center panel was changed in width every 0.1 m from 0.4 m to 0.8 m to calculate wind loads. The entire power generation panel unit 101 had a width of 1 m. A wind speed was 20 m/s. FIG. 7C shows results in which the larger one of wind loads when the first center panel was located on upwind and downwind sides of the panels around the center panel was selected. As shown in FIG. 7A, there were no abruptly reduced wind loads. In particular, when the center panel was located on the downwind side, the wind load received on the panels was not reduced.

To clarify the occurrence mechanism of this phenomenon, flow line distributions and forces received on an upwind surface of the panel unit (front surfaces of the panels) and a downwind surface of the panel unit (back surfaces of the panels) were examined.

FIGS. 8A, 8B, and 8C show schematic views of wind flows near the power generation panel unit 101. Those figures are sectional views when power generation panel unit 101 is taken at its center in a longitudinal direction. In FIGS. 8A and 8B, the first panel 102 is located on an upwind side of the second panel 103 and the third panel 104. In FIG. 8C, the first panel 102 is located on a downwind side of the second panel 103 and the third panel 104.

As shown in FIGS. 8A and 8B, when the first panel 102 is located on the upwind side of the second panel 103 and the third panel 104, wind W1 hitting onto the first panel 102 flows along a front surface thereof to outside, as indicated by arrows AR1.

When the first panel 102 is gradually increased in width (specifically, when the first panel 102 has a width of 0.5 m or more), as shown in FIG. 8A, air flows AR2 which flow into the gap G1 between the first panel 102 and the second panel 103 and the gap G2 between the first panel 102 and the third panel 104 flow along a back surface (downwind surface) of the first panel 102, as indicated by arrows AR3. As a result, an absolute value of a negative pressure received on the back surface (downwind surface) of the first panel 102 becomes lower. A wind load received on the entire panel unit is thus reduced. As shown in FIG. 8D, the gap G1 between the first panel 102 and the second panel 103 means a gap between the back surface of the first panel 102 and a front surface of the second panel 103. Difference in level DL between the first panel 102 and the second panel 103 is a dimension between the front surface of the first panel 102 and the front surface of the second panel 103 or a total dimension of a thickness of the first panel 102 and a dimension of the gap.

When the first panel 102 is further increased in width (specifically, when the first panel 102 has a width of 0.7 m or more), amounts of air flows AR1 which flow along the front surface of the first panel 102 to outside are increased. As shown in FIG. 8B, the air flows do not flow into the gap G1 between the first panel 102 and the second panel 103 and the gap G2 between the first panel 102 and the third panel 104. Air streams AR1 flowing along the front surface of the first panel 102 collide with the wind W1 directing to the second panel 103 and the third panel 104 to blow away the wind W1 to outside, as indicated by arrows AR4. As a result, positive pressures received on the front surface (upwind surface) of the second panel 103 and a front surface (upwind surface) of the third panel 104 become lower. A wind load received on the entire panel unit is thus reduced.

When the first panel 102 is located on the downwind side of the second panel 103 and the third panel 104 (when the first panel 102 is the same width as FIG. 8. A and has a width of 0.4 m or more), as shown in FIG. 8C, the wind W1 hitting onto the first panel 102 flows along the front surface of the first panel 102 to outside, as indicated by arrows AR5. Then, the wind W1 passes through the gap G1 between the first panel 102 and the second panel 103 and the gap G2 between the first panel 102 and the third panel 104, and flows to outside along a back surface (downwind surface) of the second panel 103 and a back surface (downwind surface) of the third panel 104, as indicated by arrows AR6.

Since the gap G1 between the first panel 102 and the second panel 103 and the gap G2 between the first panel 102 and the third panel 104 are narrow, the amounts of the air flows flowing into the gaps are large to increase their flow speed, so that the flows indicated by ARE occur.

When the first panel 102 is gradually increased in width, the air flows AR5 which flow along the front surface of the first panel 102 flow along the back surface (downwind surface) of the second panel 103 and the back surface (downwind surface) of the third panel 104. As a result, absolute values of negative pressures received on the back surface (downwind surface) of the second panel 103 and the back surface (downwind surface) of the third panel 104 become lower. A wind load received on the entire panel unit is thus reduced.

From the above results, the mechanism in which a wind load becomes lower is caused because the wind W1 hitting onto the first center panel 102 flows along the front surface thereof to collide with the wind W1 flowing to the adjacent panels 103 and 104 and flows along the back surfaces (downwind surfaces) of the adjacent panels 103 and 104.

From this configuration, even when the gap G1 between the adjacent panels 102 and 103 and the gap G2 between the adjacent panels 102 and 104 are the same, when panel thicknesses are different, differences in level are different. When as shown in FIG. 8C, in the arrangement in which the first panel 102 was located on the downwind side of the second panel 103 and the third panel 104, a case was studied where dimensions of the gaps were the same and differences in level became larger, that is, panel thicknesses became larger, so that the wind load reduction obtained in FIGS. 6, 7A, and 7B was not found. In a flow line distribution examination, flows were separated from outer walls of the panels to increase resistance. In addition, since the air flows were stagnant and accumulated on the front surface (upwind surface) of the first center panel, the amounts of the air flows flowing in the gaps between the adjacent panels were reduced. Further, the air flows did not flow along the back surfaces (downwind surfaces) of the panels.

When the center panel is located on the downwind side of the panels therearound, its area of the center panel is smaller in two-axis symmetry than in one-axis symmetry. In addition, a length of an end of the center panel forming differences in level between the center panel and the panels therearound is longer than the area of the center panel. Therefore, when the center panel is located on the downwind side of the panels therearound, the amounts of the air flows caused from wind which hits onto the front surface of the center panel to flow into the back surfaces of the panels therearound become smaller in two-axis symmetry than in one-axis symmetry. Consequently, no negative pressure can be eliminated.

In the panel unit made by the present inventors this time, the phenomenon in which a wind load can be reduced even when wind blows to the panel unit from either side thereof is specific to the panel configuration which basically has three panels at two stages to arrange the center panel and the two adjacent panels on both sides of the center panel by providing small differences in level with the gaps in a direction perpendicular to the front surface of the center panel.

From the above mechanism, air flows flow in a width direction of the panels from the first panel 102 to the second panel 103 and the third panel 104 or from the second panel 103 and the third panel 104 to the first panel 102, thereby reducing a wind load. Like the beams 115 shown in FIGS. 4 and 17, to support the panels, the width direction of the panels is required to be longitudinal. When the length direction of the panels is longitudinal, flows of air flows between the panels should not be inhibited.

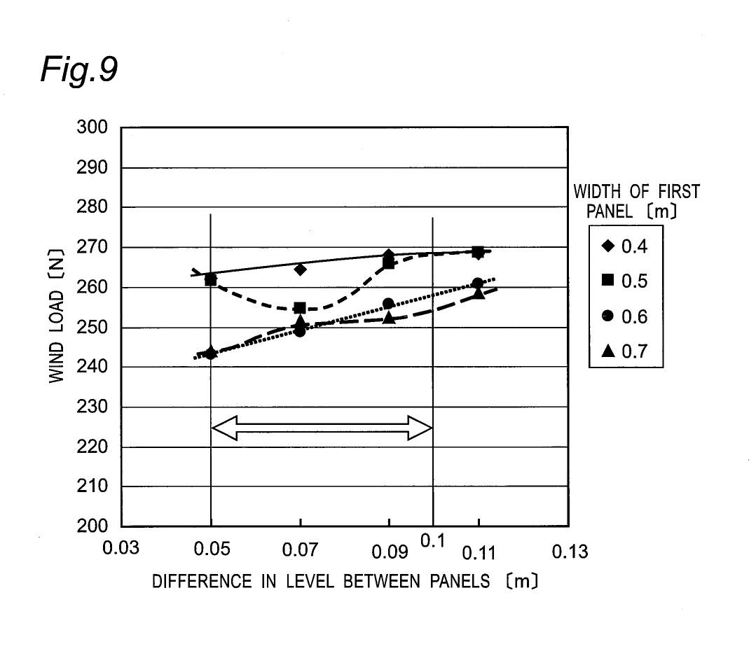

FIGS. 9 and 7B show a relation between differences in level between the panels and wind loads. In FIGS. 9 and 7B, the first center panel 102 had widths of 0.4 m, 0.5 m, 0.6 m, and 0.7 m. The power generation panels 102, 103, and 104 were three symmetric panels at two stages and each of the panels had a strip shape with a length of 1 m and a thickness of 3 cm. The entire panel unit had a width of 1 m. A wind speed was 20 m/s. The larger one of wind loads of wind which blew to the panels from directions perpendicular to front and back surfaces thereof was selected. With reference to FIGS. 9 and 7B, when difference in level DL between the panels was 0.05 m to 0.1 m, the wind loads were low.

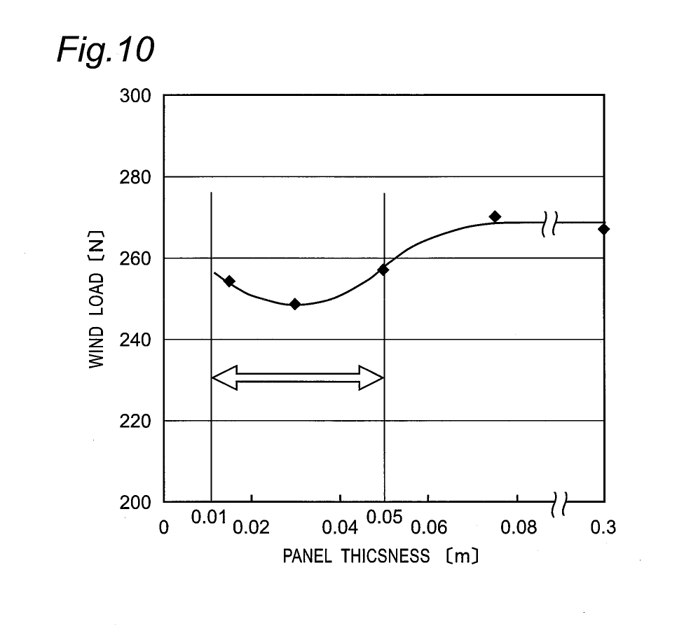

FIG. 10 shows a relation between thicknesses of the panel and wind loads. The panels 102, 103, and 104 were three symmetric panels at two stages, each of the panels having a strip shape with a length of 1 m. A dimension of a gap between the adjacent panels was 4 cm. The first center panel 102 had a width of 0.6 m. The panels 103 and 104 on both sides each had a width of 0.2 m. A wind speed was 20 m/s. The larger one of wind loads of wind which blew to the panels from directions perpendicular to front and back surfaces thereof was selected. With reference to FIG. 10, when panel thickness was 0.01 m to 0.05 m, the wind loads were low.

In the above panel shapes, the entire power generation panel unit 101 had a width of 1 m and a length of 1 m. In fluid dynamics, similarity is determined according to a shape ratio and a Reynolds number. The Reynolds number is a dimensionless number obtained by dividing the product of a wind speed and a length by a viscosity of a fluid. The viscosity of the fluid is fixed when a matter is determined. In this case, the matter is air. To establish complete similarity, the product of a wind speed and a length is constant.

In the above study, the wind speed was 20 m/s. In the below study, wind loads and flow line distributions are studied when the wind speed was changed from 2 m/s to 60 m/s.

The panels 102, 103, and 104 each had a strip shape with a length of 1 m and a thickness of 3 cm. The first panel 102 had a width of 0.6 m. The second panel 103 and the third panel 104 each had a width of 0.2 m. A difference in level was 7 cm.

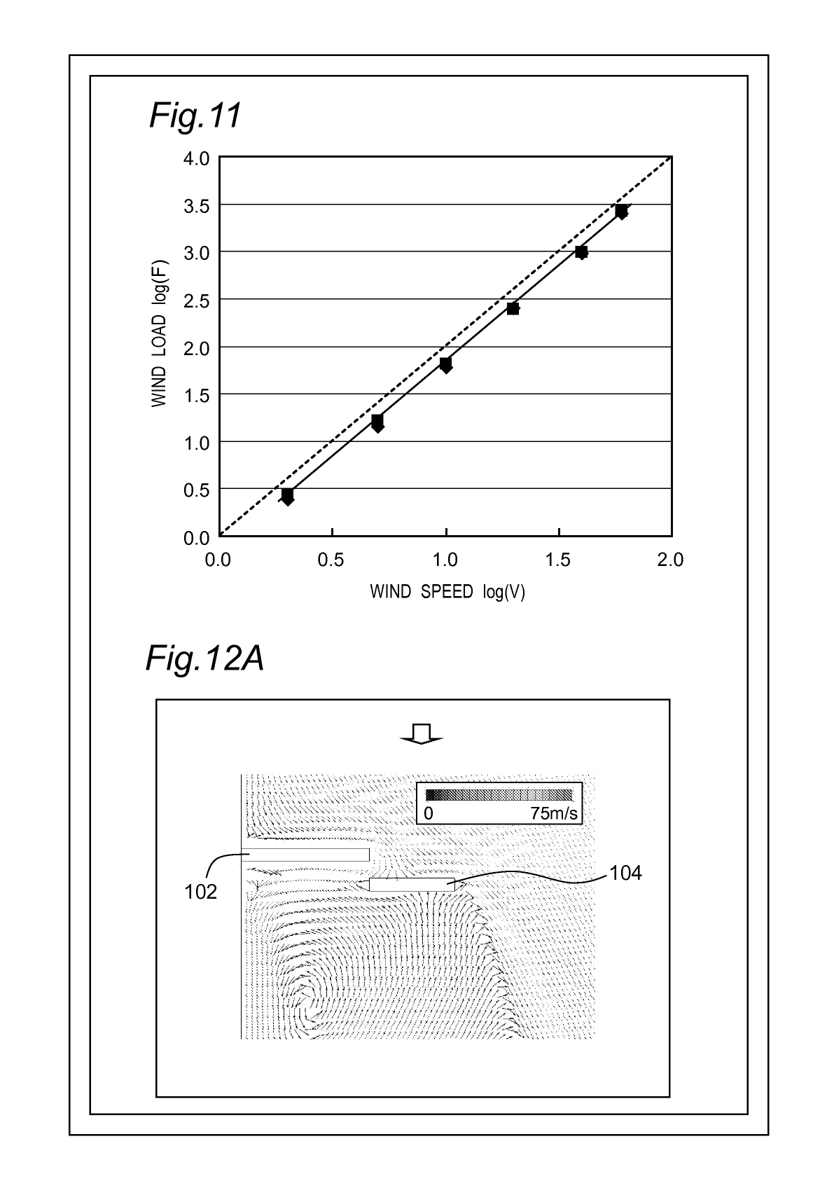

FIG. 11 shows a relation between changed wind speeds and wind loads. For each diamond mark in FIG. 11, the first center panel 102 was located on an upwind side of the second panel 103 and the third panel 104. For each square mark in FIG. 11, the first center panel 102 was located on a downwind side of the second panel 103 and the third panel 104. In these two cases, lines connecting the adjacent same marks are substantially overlapped with each other. The dashed line in FIG. 11 is a straight line passing through an origin of an inclination of 2. The marks are distributed to be parallel to this straight line. Since the inclination of the lines connecting the adjacent same marks is 2, the wind loads are in proportion to the square of each wind speed.

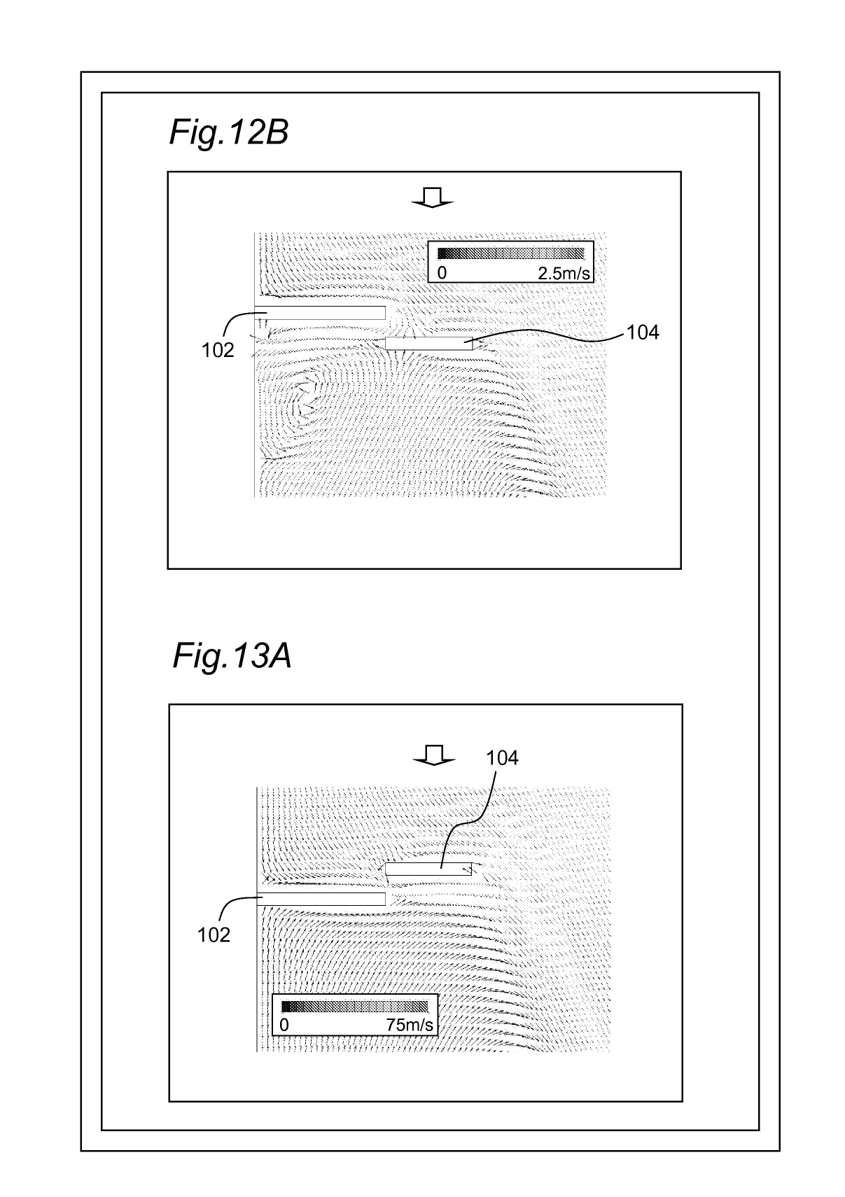

The flow speed distributions will be compared. In FIGS. 12A and 12B, the first panel 102 is located on an upwind side of the second panel 103 and the third panel 104. In FIGS. 12A and 12B, wind blows downward from above. Here, for a steady state, in consideration of the symmetry of the configuration of the power generation panel unit 101, only a flow speed distribution in a half portion of the configuration of the power generation panel unit 101 is shown. A left end line is a symmetry line. In FIG. 12A, a wind speed is 60 m/s. In FIG. 12B, a wind speed is 2 m/s. In FIGS. 12A and 12B, it is found that an air passes through a gap between the panels, and then flows along a back surface (downwind surface) of the first panel 102.

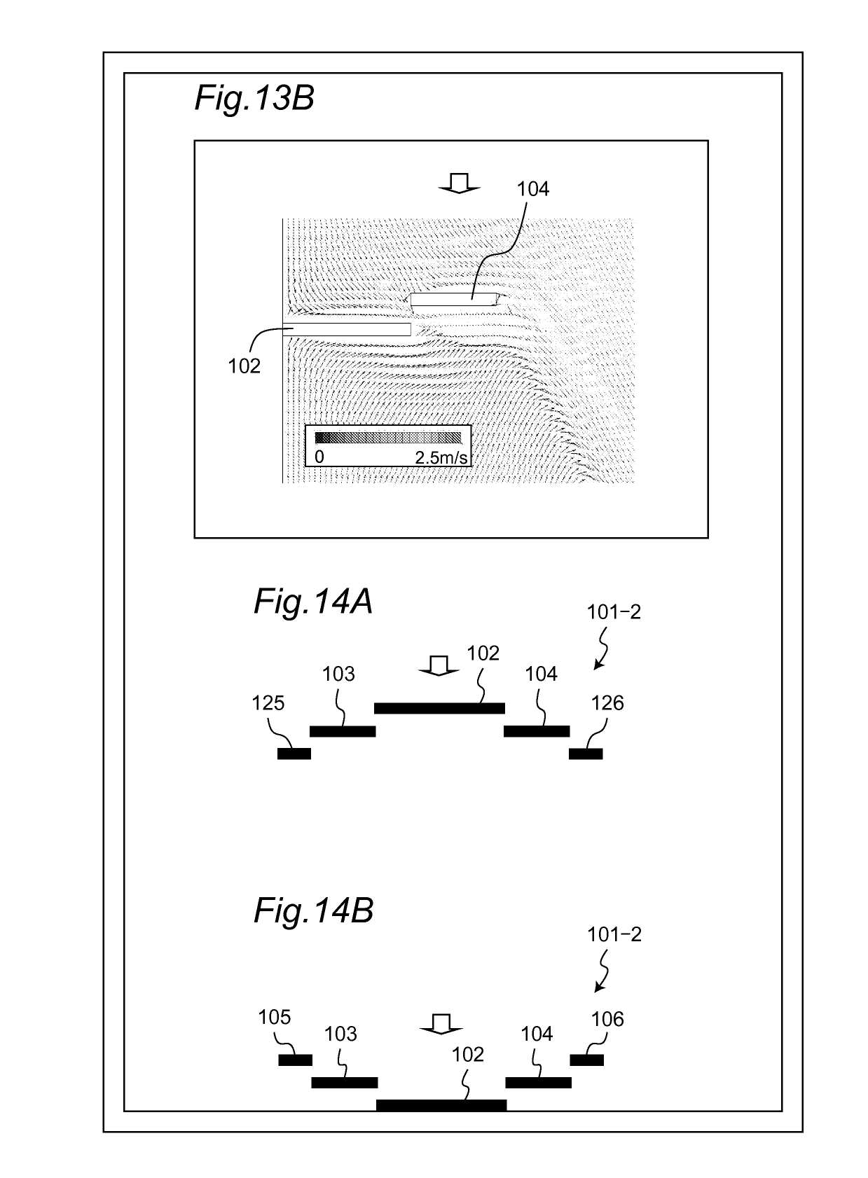

In FIGS. 13A and 13B, the first panel 102 is located on a downwind side of the second panel 103 and the third panel 104. Here, in consideration of the symmetry of the configuration of the power generation panel unit 101, only a flow speed distribution in a half portion of the configuration of the power generation panel unit 101 is shown. A left end line is a symmetry line. In FIG. 13A, a wind speed is 60 m/s. In FIG. 13B, a wind speed is 2 m/s. In FIGS. 13A and 13B, it is found that an air passes through a gap between the panels, and then flows along a back surface (downwind surface) of each of the second panel 103 and the third panel 104.

From the above, even when the wind speed is changed from 2 m/s to 60 m/s, the mechanism of the phenomenon according to the embodiment of the present invention can be maintained.

In the above study, the wind speed was 20 m/s. The panels are assumed to be similar in wind speed in a range of from 1/10 times to three times. Therefore, the panels can be assumed to be similar in length in a range of at least from ⅓ times to 10 times.

In the above study, the length of a side of each of the panels and the width of the entire panel unit were 1 m. The length in a range of from ⅓ m to 10 m is thus applicable. The similar shape is established when ratios, not lengths, are the same. This means that the above contents described with “m” as a length unit are established at a ratio without “m”

Therefore, a wind load becomes lower even when wind blows to each of the panels from either direction thereof when the width of the first center panel 102 is three times or more the width of each of the second panel 103 and the third panel 104 on both sides and when a ratio of a difference in level between the adjacent panels to the width of the entire panel unit of 1 is 0.05 to 0.1.

A ratio of a thickness of each of the panels to the width of the entire panel unit of 1 may be 0.01 to 0.05.

In the solar power generation panel unit 101 of the configuration of the first embodiment of the present invention and the solar power generation apparatus 810 mounting thereon, the power generation panel unit 101 can make a wind load received on each of the panels lower than the conventional art even when wind blows to the power generation panel unit 101 from either the front or back surface thereof.

The number of panels is small, the panels are thin, and a difference in level between the adjacent panels is small. The number of members connecting the panels is small to reduce the weight of the panels including peripheries thereof. Therefore, any load and moment onto the supporting post 107 supporting all the first to third panels 102, 103, and 104 can be reduced to improve safety. In addition, energy moving the first to third panels 102, 103, and 104 can be reduced.

When each of the panels has a length less than 1 m, the power generation module 105 is thinner to reduce the thickness of the light concentrating member. In this case, a focal length is required to be within the thickness of the power generation module 105, as an example, the light concentrating member and the power generation element are directly joined. The reason of such a configuration is as follows. That is, since air has a refraction factor of 1, as compared with when the power generation element has only the optical member, when the power generation module 105 has an air layer sandwiched between the light concentrating member and the power generation element, not only an actual optical path length, but also the number of interfaces, is increased. Due to this, interface reflection reduces the amount of light incident onto the power generation element. To improve an assembling precision and rigidity of the power generation module, as an example, the light concentrating member and the power generation element are directly joined.

As an example, in particular, the light concentrating member which is formed of a transparent resin is required to have a thickness less than 10 mm. The light concentrating member and the power generation element are thus directly joined. This is caused by the fact that the resin absorbs light having a material-specific wavelength of 1000 nm or more. However, when the light concentrating member is formed only of the transparent resin, the focal length cannot be obtained. In this case, glass having a refraction factor close to that of the transparent resin is used together with the transparent resin. The reduced amount of transmitted light due to interface reflection can be prevented.

The light concentrating member which is formed of the transparent resin can be reduced in weight. The effect in which the panels are small to be reduced in weight can thus be improved. That is, power consumption of the motors driving the panels can be reduced.

On the other hand, when the length of each of the panels becomes larger to be LL and the like, the light concentrating member of the power generation module 105 also becomes larger. In this case, each of the panels becomes heavy. Since the length between the light concentrating member and the power generation element is still long, the air layer is provided to reduce the weight although the efficiency is lowered due to interface reflection.

### Second Embodiment

FIGS. 14A and 14B show cross-sectional views of a solar power generation panel unit 101-2 according to a second embodiment of the present invention, taken at its center in a longitudinal direction.

The power generation panel unit 101 of the first embodiment of the present invention has three strip-shaped panels at two stages. The power generation panel unit 101-2 of the second embodiment of the present invention has five panels at three stages. That is, in the power generation panel unit 101-2, a fourth panel 125 is arranged on the opposite side of the first panel 102 from the second panel 103 in the power generation panel unit 101, and a fifth panel 126 is arranged on the opposite side of the first panel 102 from the third panel 104 in the power generation panel unit 101. The fourth panel 125, the f ifth panel 126, the first panel 102, the second panel 103, and the third panel 104 have the same length PL, and are parallel to each other.

A width of each of the fourth panel 125 and the fifth panel 126 is equal to or less than a width UL each of the second panel 103 and the third panel 104. Reversely, the width of each of the inner panels 103 and 104 is equal to or more than the width of each of the outer panels 125 and 126.

In FIG. 14A, the first center panel 102 at the first stage is located on an upwind side of the panels 103, 104, 125, and 126. In FIG. 14B, the first center panel 102 at the first stage is located on a downwind side of the panels 103, 104, 125, and 126. Each arrow indicates a direction of wind.

The power generation panels 102 to 126 each had a strip shape with a length of 1 m and a thickness of 3 cm. The entire panel unit had a width of 1 m. A difference in level was 7 cm. A uniform flow at a wind speed of 20 m/s was incident perpendicularly to front surfaces of the panels to numerically analyze wind loads. The first panel 102 at the first stage had a width of 0.6 m. The second panel 103 and the third panel 104 at the second stage each had a width of 0.15 m. The fourth panel 125 and the fifth panel 126 at the third stage each had a width of 0.05 m. In this case, in the arrangement in FIG. 14A, a wind load was 220 N, and in the arrangement in FIG. 14B, a wind load was 249N. Therefore, as with two stages, even with three stages, the wind loads were lower than the conventional art even when wind blew to the power generation panel unit 101-2 from either front or back surface thereof.

In the power generation panel unit 101-2, the width of the first center panel 102 was larger than the width of each of the second panel 103 and the third panel 104 on the outer side. The width of the first panel 102 at the first stage was three times the width of each of the second panel 103 and the third panel 104 at the second stage. In addition, when the width of the entire power generation panel unit 101-2 was 1, a ratio of the difference in level between the adjacent panels was 0.07, a ratio of a dimension of a gap between the adjacent panels was 0.04, and a ratio of the thickness of each of the panels was 0.03.

Therefore, the width of the first panel 102 at the first stage is three times or more the width of each of the second panel 103 and the third panel 104 at the second stage. In addition, when the width of the entire power generation panel unit 101-2 is 1, the ratio of the difference in level between the adjacent panels is 0.05 to 0.1.

As in the first embodiment with two stages, according to the solar power generation panel unit 101-2 and the solar power generation apparatus according to the second embodiment, even with three stages, a load wind received on each of the panels is lower than the conventional art even when wind blows to the power generation panel unit 101-2 from either the front or back surface thereof.

### Third Embodiment

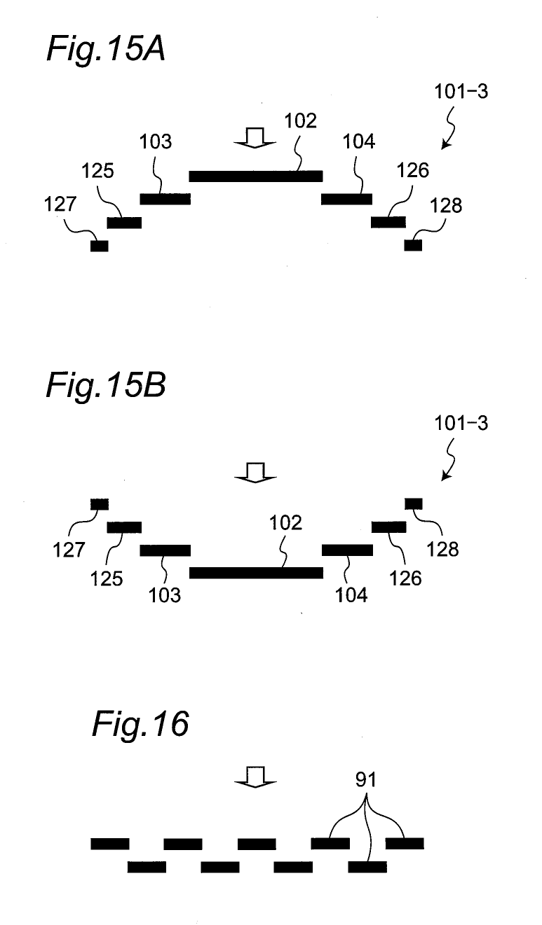

FIGS. 15A and 15B show cross-sectional views of a solar power generation panel unit 101-3 according to a third embodiment of the present invention, taken at its center in a longitudinal direction.

The power generation panel unit 101 of the first embodiment of the present invent ion has three strip-shaped panels at two stages. The power generation panel unit 101-3 of the third embodiment of the present invention has seven panels at four stages. That is, in the power generation panel unit 101-3, a sixth panel 127 is arranged on the opposite side of the second panel 103 from the fourth panel 125 in the power generation panel unit 101-2, and a seventh panel 128 is arranged on the opposite side of the third panel 104 from the fifth panel 126 in the power generation panel unit 101-2. The sixth panel 127, the seventh panel 128, the first panel 102, and the second panel 103 to the fifth panel 126 have the same length PL, and are parallel to each other.

In addition, a width of each of the sixth panel 127 and the seventh panel 128 is equal to or less than a width of each of the second panel 103 and the third panel 104, and is equal to or less than a width of each of the fourth panel 125 and the fifth panel 126.

In FIG. 15A, the first center panel 102 at the first stage is located on an upwind side of the panels 103, 104, 125, 126, 127, and 128. In FIG. 15B, the first center panel 102 at the first stage is located on a downwind side of the panels 103, 104, 125, 126, 127, and 128. Each arrow indicates a direction of wind.

The power generation panels 102 to 128 each had a strip shape with a length of 1 m and a thickness of 3 cm. The entire panel unit had a width of 1 m. A difference in level was 7 cm. A uniform flow at a wind speed of 20 m/s was incident perpendicularly to front surfaces of the panels to numerically analyze wind loads. The first panel 102 at the first stage had a width of 0.5 m. The second panel 103 and the third panel 104 at the second stage each had a width of 0.15 m. The fourth panel 125 and the fifth panel 126 at the third stage each had a width of 0.05 m. The sixth panel 127 and the seventh panel 128 at the fourth stage each had a width of 0.05 m. In this case, in the arrangement in FIG. 15A, a wind load was 202 N, and in the arrangement in FIG. 15B, a wind load was 248 N. As with two and three stages, even with four stages, the wind loads were lower than the conventional art even when wind blew to the power generation panel unit 101-3 from either front or back surface thereof.

In the power generation panel unit 101-3, the width of the first center panel 102 was larger than the width of each of the second panel 103 and the third panel 104 on the outer side. In addition, the width of the first panel 102 at the first stage was three times or more the width of each of the second panel 103 and the third panel 104 at the second stage. Further, when the width of the entire power generation panel unit 101-3 was 1, a ratio of the difference in level between the adjacent panels was 0.07, a ratio of a dimension of a gap between the adjacent panels was 0.04, and a ratio of the thickness of each of the panels was 0.03.

Therefore, the width of the first panel 102 at the first stage is three times or more the width of each of the second panel 103 and the third panel 104 at the second stage. In addition, when the width of the entire power generation panel unit 101-3 is 1, the ratio of the difference in level between the adjacent panels is 0.05 to 0.1.

From the above results, as in the first embodiment with two stages and the second embodiment with three stages, in the power generation panel unit 101-3 according to the third embodiment with four stages, a load wind is lower than the conventional art even when wind blows to the power generation panel unit 101-3 from either the front or back surface thereof.

Therefore, according to the first to third embodiments with two or more stages, a load wind is lower than the conventional art even when wind blows to the power generation panel unit 101-3 from either the front or back surface thereof.

### Modification Examples

In the first to third embodiments, corners of each of the panels of the solar power generation panel unit are sharp with a right angle, but may be rounded or chamfered. When the corners are eliminated, an air stream is unlikely to be separated from the front surface of each of the panels to reduce a wind load. In FIG. 17, as an example, corners of each of the panels of the power generation panel unit 101 of the first embodiment are rounded.

No rotation moment is applied onto the supporting post 107 supporting each of the panels. Therefore, the panel unit has a symmetric shape with respect to a plane perpendicular to the front wide surface of the first panel 102 and passing through a center line of the width of the first center panel 102. However, the panel unit according to the present invention which is within the described conditions may not be symmetric. Specifically, as an example, the panel unit may not be symmetric in the range in which a difference in dimension between the symmetric panels does not exceed two times.

In the first to third embodiments, the power generation module of the solar power generation panel unit is of the concentrating type. However, even when wind blows to the panels from either the front or back surface thereof, the wind load reducing effect depends on the configuration of the panel unit, not on whether the panels themselves are of the concentrating type or the normal type. Therefore, the present invention is applicable to the normal type solar power generation panel unit.

In the first to third embodiments, the first panel 102 to the seventh panel 108 have the same length. However, the present invention is not limited to this. For instance, in consideration of an error in manufacture or change with time, the first panel 102 to the seventh panel 108 may have the same length in the range of ±0.01 times.

In the first to third embodiments, the first panel 102 to the seventh panel 108 have the same thickness T. However, for instance, in consideration of an error in manufacture or change with time, the first panel 102 to the seventh panel 108 may have the same thickness T in the range of ±0.005 times.

In the first to third embodiments, the longitudinal direction of each of the first panel 102, the second panel 103, and the third panel 104 is the same as the longitudinal direction of the supporting post 107. In other words, in a plane seen from the front surface of the power generation panel unit 101, a border line between the first panel 102 and the second panel 103 or the third panel 104 does not cross the longitudinal direction of the supporting post 107. When the power generation panel unit 101 shown in FIG. 2 is seen from the lateral direction, the second panel and the third panel are closer to the supporting post than the first panel 102. However, as long as the second panel and the third panel satisfy the relations between the widths and the differences in level between the panels shown in the first to third embodiments, the second panel and the third panel may be farther away from the supporting post 107 than the first panel 102.

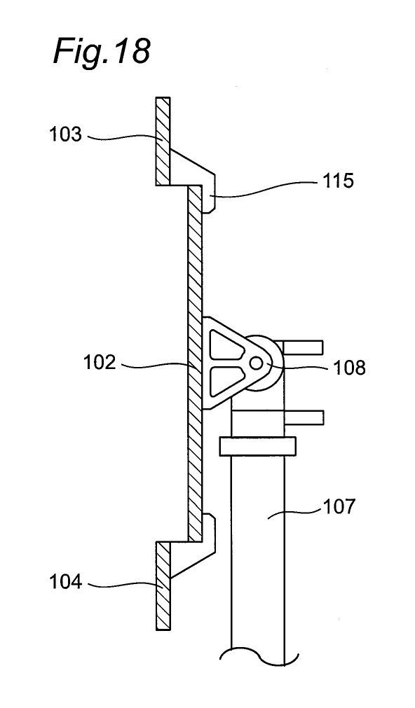

The longitudinal direction of each of the first panel 102, the second panel 103, and the third panel 104 can cross the longitudinal direction of the supporting post 107. FIG. 18 shows the power generation panel unit 101, seen from the longitudinal direction of the first panel 102 (the second panel 103 or the third panel 104)

The first panel 102 is located to be closer to the supporting post 107 than the second panel 103 and the third panel 104. In other words, in a plane seen from the front surface of the power generation panel unit 101, when the border line between the first panel 102 and the second panel 103 or the third panel 104 crosses the longitudinal direction of the supporting post 107, the first panel 102 is located to be closer to the supporting post than the second panel 103 and the third panel 104.

Of course, it is necessary to provide a distance between the first panel 102 and the supporting post 107 so that the beams 115 connecting and fixing the first panel 102, the second panel 103, and the third panel 104 do not come into contact with the supporting post 107 and a flange fixing the azimuth driving device 110 to the supporting post.

Without changing the distance between the first panel 102 and the supporting post 107, when the second panel 103 and the third panel 104 are located to be closer to the supporting post 107 than the first panel 102, at the time of driving the power generation panel unit 101 by the elevation angle driving device 109, there is a possibility that the second panel 103 and the third panel 104 can come into contact with the supporting post 107 and the flange fixing the azimuth driving device 110 to the supporting post 107. The distance between the first panel 102 and the supporting post 107 affects a force for driving the power generation panel unit 101; therefore, the distance can be minimum. The first panel 102 is located to be closer to the supporting post 107 than the second panel 103 and the third panel 104. Therefore, the power generation panel unit 101 can be driven by a smaller force. In addition, the possibility that the second panel 103 and the third panel 104 come into contact with the supporting post 107 can thus be reduced.

By properly combining the arbitrary embodiment (s) or modification (s) of the aforementioned various embodiments and modifications, the effects possessed by the embodiment (s) or modification(s) can be produced.

### INDUSTRIAL APPLICABILITY

The solar power generation panel unit and the solar power generation apparatus according to the present invention can reduce an influence of wind blowing to the panel unit from both sides thereof, and are useful as power generation equipment using sunlight as natural energy.

Although the present invention has been fully described in connection with the embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

1-14. (canceled)

15. A solar power generation panel unit comprising:
a first panel;
a second panel that is arranged on one side of the first panel in a width direction; and
a third panel that is arranged on an other side opposite to the one side of the first panel in the width direction,
wherein the first panel, the second panel, and the third panel have an identical length and are parallel to each other so that a difference in level is provided between the first panel and the second panel with a gap in a direction perpendicular to front surfaces of the first and second panels and that a difference in level is provided between the first panel and the third panel with a gap in a direction perpendicular to front surfaces of the first and third panels,
wherein a width of the first panel is three times or more a width of the second panel and is three times or more a width of the third panel,
wherein when a width of an entire panel unit as a total of the widths of the first panel, the second panel, and the third panel is 1, a ratio of the difference in level between the front surface of the first panel and the front surface of the second panel is 0.05 to 0.1.

16. The solar power generation panel unit according to claim 15, wherein when the width of the entire panel unit is 1, a ratio of a dimension of the gap obtained by subtracting a thickness of the first panel from the difference in level between the front surface of the first panel and the front surface of the second panel is 0.02 to 0.07.

17. The solar power generation panel unit according to claim 15, wherein when the width of the entire panel unit is 1, a ratio of a thickness of each of the panels is 0.01 to 0.05.

18. The solar power generation panel unit according to claim 16, wherein when the width of the entire panel unit is 1, a ratio of a thickness of each of the panels is 0.01 to 0.05.

19. The solar power generation panel unit according to claim 15, wherein the second panel and the third panel are symmetric with respect to a plane perpendicular to the front surface of the first panel and passing through a center axis in the width direction.

20. The solar power generation panel unit according to claim 16, wherein the second panel and the third panel are symmetric with respect to a plane perpendicular to the front surface of the first panel and passing through a center axis in the width direction.

21. The solar power generation panel unit according to claim 15, wherein the panels are supported in a width direction or a thickness direction of the panels.

22. The solar power generation panel unit according to claim 16, wherein the panels are supported in a width direction or a thickness direction of the panels.

23. The solar power generation panel unit according to claim 15, wherein each of the panels has a plurality of concentrating solar power generation elements.

24. The solar power generation panel unit according to claim 16, wherein each of the panels has a plurality of concentrating solar power generation elements.

25. The solar power generation panel unit according to claim 23, wherein a light concentrating member that covers each of the concentrating solar power generation elements is not overlapped with adjacent panels in the direction perpendicular to the front surfaces of the panels.

26. The solar power generation panel unit according to claim 23, wherein an air layer is not provided between the concentrating solar power generation element and the light concentrating member.

27. A solar power generation panel unit comprising:
a first panel;
a second panel that is arranged on one side of the first panel in a width direction; and
a third panel that is arranged on an other side opposite to the one side of the first panel in the width direction,
wherein the first panel is arranged on an upwind side of the second panel and the third panel,
wherein the first panel, the second panel, and the third panel have an identical length and are parallel to each other so that a difference in level is provided between the first panel and the second panel with a gap in a direction perpendicular to front surfaces of the first and second panels and that a difference in level is provided between the first panel and the third panel with a gap in a direction perpendicular to front surfaces of the first and third panels,
wherein a width of the first panel is three times or more a width of the second panel and is three times or more a width of the third panel,
wherein wind incident onto the front surface of the first panel forms air streams directing to both sides along the front surface of the first panel, and the air streams directing to both sides along the front surface of the first panel collide with wind directing to the second panel and the third panel before reaching the second panel and the third panel to blow away the wind directing to the second panel and the third panel to outside of the second panel and the third panel.

28. A solar power generation panel unit comprising:
a first panel;
a second panel that is arranged on one side of the first panel in a width direction; and
a third panel that is arranged on an other side opposite to the one side of the first panel in the width direction,
wherein the first panel is arranged on a downwind side of the second panel and the third panel,
wherein the first panel, the second panel, and the third panel have an identical length and are parallel to each other so that a difference in level is provided between the first panel and the second panel with a gap in a direction perpendicular to front surfaces of the first and second panels and that a difference in level is provided between the first panel and the third panel with a gap in a direction perpendicular to front surfaces of the first and third panels,
wherein a width of the first panel is three times or more a width of the second panel and is three times or more a width of the third panel,
wherein wind incident onto the front surface of the first panel forms air streams directing to both sides along the front surface of the first panel, and the air streams enter into the gap between the first panel and the second panel and the gap between the first panel and the third panel to flow along a back surface of the second panel and a back surface of the third panel.

29. A solar power generation panel unit comprising:
a first panel;
a second panel that is arranged on one side of the first panel in a width direction; and
a third panel that is arranged on an other side opposite to the one side of the first panel in the width direction,
wherein the first panel is arranged on an upwind side of the second panel and the third panel,
wherein the first panel, the second panel, and the third panel have an identical length and are parallel to each other so that a difference in level is provided between the first panel and the second panel with a gap in a direction perpendicular to front surfaces of the first and second panels and that a difference in level is provided between the first panel and the third panel with a gap in a direction perpendicular to front surfaces of the first and third panels,
wherein a width of the first panel is three times or more a width of the second panel and is three times or more a width of the third panel,
wherein wind incident onto the front surface of the first panel forms air streams directing to both sides along the front surface of the first panel, and the air streams enter into the gap between the first panel and the second panel and the gap between the first panel and the third panel to flow along a back surface of the first panel.

30. A solar power generation apparatus comprising:
the solar power generation panel unit according to claim 15;
a posture driving section that independently moves the solar power generation panel unit in an elevation angle direction and in an azimuth direction;
a supporting post that supports all the panels; and
a controller that controls the posture driving section to allow a direction of the solar power generation panel unit to track sun based on information from the posture driving section.

31. A solar power generation apparatus comprising:
the solar power generation panel unit according to claim 16;
a posture driving section that independently moves the solar power generation panel unit in an elevation angle direction and in an azimuth direction;
a supporting post that supports all the panels; and
a controller that controls the posture driving section to allow a direction of the solar power generation panel unit to track sun based on information from the posture driving section.

32. The solar power generation apparatus according to claim 30, wherein a longitudinal direction of each of the first panel, the second panel, and the third panel is arranged along a longitudinal direction of the supporting post.

33. The solar power generation apparatus according to claim 30, wherein when a border line between the first panel and the second panel or the third panel in a plane seen from the front surfaces of the first panel, the second panel, and the third panel crosses the longitudinal direction of the supporting post, the first panel is closer to the supporting post than the second panel and the third panel.
